(19) United States
(12) Patent Application Publication
(10) Pub. No.: US 2006/0130891 A1
(43) Pub. Date: Jun. 22, 2006

(54) Back-contact photovoltaic cells

(76) Inventor: David E. Carlson, Williamsburg, VA (US)

Correspondence Address: CAROL WILSON;BP AMERICA INC., MAIL CODE 5 EAST, 4101 WINFIELD ROAD, WARRENVILLE, IL, 60555, US

(21) Appl. No.: 11/259,979

(22) Filed: Oct. 27, 2005

Related U.S. Application Data
(60) Provisional application No. 60/623,452, filed on Oct. 29, 2004.

(51) Int. Cl. H01L 31/00

(52) U.S. Cl. 136/256; 136/259; 136/246

(57) ABSTRACT

A photovoltaic cell comprising a wafer comprising a semiconductor material of a first conductivity type, the wafer comprising a first light receiving surface and a second surface opposite the first surface; a first passivation layer positioned over the first surface of the wafer; a first electrical contact positioned over the second surface of the wafer; a second electrical contact positioned over the second surface of the wafer and separated electrically from the first electrical contact; a second passivation layer positioned over the second surface of the wafer in the region on the wafer that is at least between the first electrical contact and the second surface of the wafer; and a layer comprising a semiconductor material of a conductivity opposite the conductivity of the wafer and positioned in the region between the second passivation layer and the first contact.

This application claims the benefit of U.S. Provisional Patent Application Ser. No. 60/623,452, filed on Oct. 29, 2004.

### BACKGROUND OF THE INVENTION

This invention relates to new photovoltaic cells. More particularly, this invention relates to photovoltaic cells that are highly efficient in converting light energy, and particularly solar energy, to electrical energy and where such cells have electrical contacts on the back surface. This invention is also a process for making such cells.

One of the most important features of a photovoltaic cell is its efficiency in converting light energy from the sun into electrical energy. Another important feature is the ability to manufacture such cell in a manner applicable to large-scale manufacturing processes. Thus, the art is continuously striving to not only improve the efficiency of photovoltaic cells in converting light energy into electrical energy, but also to manufacture them using safe, environmentally compatible, large-scale manufacturing processes.

Although photovoltaic cells can be fabricated from a variety of semiconductor materials, silicon is generally used because it is readily available at reasonable cost and because it has the proper balance of electrical, physical and chemical properties for use in fabricating photovoltaic cells. In a typical procedure for the manufacture of photovoltaic cells using silicon as the selected semiconductor material, the silicon is doped with a dopant of either positive or negative conductivity type, formed into either ingots of monocrystalline silicon, or cast into blocks or “bricks” of what the art refers to as a multicrystalline silicon, and these ingots or blocks are cut into thin substrates, also referred to as wafers, by various slicing or sawing methods known in the art. However, these are not the only methods used to obtain suitable semiconductor wafers for the manufacture of photovoltaic cells.

By convention, positive conductivity type is commonly designated as “p” or “p-type” and negative conductivity type is designated as “n” or “n-type”. Therefore, “p” and “n” are opposing conductivity types.

The surface of the wafer intended to face incident light when the wafer is formed into a photovoltaic cell is referred to herein as the front face or front surface, and the surface of the wafer opposite the front face is referred to herein as the back face or back surface.

In a typical and general process for preparing a photovoltaic cell using, for example, a p-type silicon wafer, the wafer is exposed to a suitable n-dopant to form an emitter layer and a p-n junction on the front, or light-receiving side of the wafer. Typically, the n-type layer or emitter layer is formed by first depositing the n-dopant onto the front surface of the p-type wafer using techniques commonly employed in the art such as chemical or physical deposition and, after such deposition, the n-dopant, for example, phosphorus, is driven into the front surface of the silicon wafer to further diffuse the n-dopant into the wafer surface. This “drive-in” step is commonly accomplished by exposing the wafer to high temperatures. A p-n junction is thereby formed at the boundary region between the n-type layer and the p-type silicon wafer substrate. The wafer surface, prior to the phosphorus or other doping to form the emitter layer, can be textured.

In order to utilize the electrical potential generated by exposing the p-n junction to light energy, the photovoltaic cell is typically provided with a conductive front electrical contact on the front face of the wafer and a conductive back electrical contact on the back face of the wafer. Such contacts are typically made of one or more highly electrically conducting metals and are, therefore, typically opaque. Since the front contact is on the side of the photovoltaic cell facing the sun or other source of light energy, it is generally desirable for the front contact to take up the least amount of area of the front surface of the cell as possible yet still capture the electrical charges generated by the incident light interacting with the cell. Even though the front contacts are applied to minimize the amount of front cell surface area covered or shaded by the contact, front contacts nevertheless reduce the amount of surface area of the photovoltaic cell that could otherwise be used for generating electrical energy. The process described above also uses a number of high temperature processing steps to form the photovoltaic cells. Using high temperatures increases the amount of time needed to manufacture photovoltaic cells, consumes energy, and requires the use of expensive high temperature furnaces or other equipment for processing photovoltaic cells at high temperatures.

The art therefore needs photovoltaic cells that have high efficiency, can be manufactured using large scale production methods, and, preferably, by methods that do not utilize high temperature processing steps or, at least, use a minimum of high temperature processing steps, and where the cells, in order to increase efficiency, do not have electrical contacts on the front side or surface of the wafer, thereby maximizing the available area of the front surface of the cell for converting light into electrical current. The present invention provides such a photovoltaic cell. The photovoltaic cells of this invention can be used to efficiently generate electrical energy by exposing the photovoltaic cell to the sun.

### SUMMARY OF THE INVENTION

This invention is a photovoltaic cell comprising; a wafer comprising a semiconductor material of a first conductivity type and comprising a first, light receiving surface, a second surface opposite the first surface on the wafer, and a diffusion length; a first passivation layer positioned over the first surface of the wafer; a first electrical contact positioned over the second surface of the wafer; a second electrical contact positioned over the second surface of the wafer and separated electrically from the first electrical contact; a second passivation layer positioned over the second surface of the wafer in the region that is at least between the first electrical contact and the second surface of the wafer; and a layer comprising a semiconductor material of a conductivity opposite the conductivity of the wafer and positioned in the region between the second passivation layer and the first electrical contact.

This invention is also a process for manufacturing such a photovoltaic cell.

### BRIEF DESCRIPTION OF THE DRAWING

FIG. 1 is a cross-sectional view of a portion of a photovoltaic cell in accordance with an embodiment of this invention having point contacts.

FIG. 2 is a plan view of a portion of the photovoltaic cell of FIG. 1.

FIG. 3 is a three-dimensional view of a portion of a photovoltaic cell in accordance with an embodiment of this invention having point contacts.

FIG. 4 is a three-dimensional view of a portion of a photovoltaic cell in accordance with an embodiment of this invention having point contacts.

FIG. 5 is a block diagram of a process in accordance with an embodiment of this invention.

FIG. 6 is a cross-sectional view of a portion of a photovoltaic cell in accordance with an embodiment of this invention having point contacts.

FIG. 7 is a plan view of a photovoltaic cell in accordance with an embodiment of this invention having interdigitated back contacts.

FIG. 8 is a three-dimensional view of a portion of the photovoltaic cell of FIG. 7.

FIG. 9 is a plan view of a photovoltaic cell in accordance with an embodiment of this invention having interdigitated back contacts.

FIG. 10 is a three-dimensional view of a portion of a photovoltaic cell of FIG. 9.

FIG. 11 is a three-dimensional view of electrical contacts in accordance with an embodiment of this invention.

### DETAILED DESCRIPTION OF THE INVENTION

The invention will now be described using, as an example, an embodiment of the invention whereby a photovoltaic cell is made using a p-type, crystalline silicon wafer. However, it is to be understood that the invention is not limited thereby and is, for example, applicable to other semiconductor materials such as an n-type crystalline silicon wafer. In addition, it is not necessary for the wafer to be crystalline. It can, for example, be multi-crystalline or sometimes referred to as polycrystalline.

A silicon wafer useful in the process of this invention for preparing photovoltaic cells is typically in the form of a thin, flat shape. The silicon may comprise one or more additional materials, such as one or more semiconductor materials, for example germanium, if desired. Although boron is widely used as the first, p-type dopant, other p-type dopants, for example, aluminum, gallium or indium, will also suffice. Boron is the preferred p-type dopant. Combinations of such dopants are also suitable. Thus, the first dopant for a p-type wafer can comprise, for example, one or more of boron, aluminum, gallium or indium, and preferably it comprises boron. Suitable wafers are typically obtained by slicing or sawing p-type silicon ingots, such as ingots of monocrystalline silicon, to form monocrystalline wafers, such as the so-called Czochralski (Cz) silicon wafers. If an n-type silicon wafer is used, the dopants can be, for example, one or more of phosphorus, arsenic, antimony, or bismuth. Suitable wafers can also be made by slicing or sawing blocks of cast, p-type multi-crystalline silicon. Silicon wafers can also be pulled straight from molten silicon using processes such as Edge-defined Film-fed Growth technology (EFG) or similar techniques. Although the wafers can be any shape, wafers are typically circular, square or pseudo-square in shape. By “pseudo-square” is meant a predominantly square shape wafer usually with rounded corners. The wafers used in the photovoltaic cells of this invention are suitably thin. For example, wafers useful in this invention can be about 10 microns thick to about 200 microns thick. The wafers used in the photovoltaic cells of this invention preferably have a diffusion length (Lₚ) that is greater than the wafer thickness (t). For example, the ratio of Lₚ to t is suitably greater than 1. It can, for example be greater than about 1.1, or greater than about 2. The diffusion length is the average distance that minority carriers (such as electrons in p-type material) can diffuse before recombining with the majority carriers (holes in p-type material). The Lₚ is related to the minority carrier lifetime τ through the relationship Lₚ=(Dτ)^{1/2} where D is the diffusion constant. The diffusion length can be measured by a number of techniques such as the Photon-Beam-Induced Current technique or the Surface Photovoltage technique. See for example, “Fundamentals of Solar Cells”, by A. Fahrenbruch and R. Bube, Academic Press, 1983, pp. 90-102, which is incorporated by reference herein, for a description of how the diffusion length can be measured.

If circular, the wafers can have a diameter of about 100 to about 180 millimeters, for example 102 to 178 millimeters. If square or pseudo square, they can have a width of about 100 millimeters to about 150 millimeters with rounded corners having a diameter of about 127 to about 178 millimeters. The wafers useful in the process of this invention, and consequently the photovoltaic cells made by the process of this invention can, for example, have a surface area of about 100 to about 250 square centimeters. The wafers doped with the first dopant that are useful in the process of this invention can have a resistivity of about 0.1 to about 20 ohm·cm, typically of about 0.5 to about 5.0 ohm·cm. Although the term wafer, as used herein, includes the wafers obtained by the methods described, particularly by sawing or cutting ingots or blocks of single crystal or multi-crystalline silicon, it is to be understood that the term wafer can also include any other suitable semiconductor substrate or layer useful for preparing photovoltaic cells by the process of this invention.

The front surface of the wafer is preferably textured. Texturing generally increases the efficiency of the resulting photovoltaic cell by increasing light absorption. For example, the wafer can be suitably textured using chemical etching, plasma etching, laser or mechanical scribing. If a monocrystalline wafer is used, the wafer can be etched to form an anisotropically textured surface by treating the wafer in an aqueous solution of a base, such as sodium hydroxide, at an elevated temperature, for example about 70° C. to about 90° C. for about 10 to about 120 minutes. The aqueous solution may contain an alcohol, such as isopropanol. A multicrystalline wafer can be textured by mechanical dicing using beveled dicing blades or profiled texturing wheels. In the preferred process of this invention, a multicrystalline wafer is textured using a solution of hydrofluoric acid, nitric acid and water. Such a texturing process is described by Hauser, Melnyk, Fath, Narayanan, Roberts and Bruton in their paper “A Simplified Process for Isotropic Texturing of MC-Si”, Hauser, et al., from the conference “3^{rd} World Conference on Photovoltaic Eneregy Conversion”, May 11-18, Osaka, Japan, which is incorporated by reference herein in its entirety. The textured wafer is typically subsequently cleaned, for example, by immersion in hydrofluoric and then hydrochloric acid with intermediate and final rinsing in de-ionized water, followed by drying.

Prior to texturing a wafer such as a multi-crystalline wafer, the wafer can be subjected to phosphorus and aluminum gettering. For example, gettering can be accomplished by forming a heavily n-doped layer by, for example, phosphorus diffusion on one or both sides of the wafer. This can be accomplished, for example, by exposing the wafer to a gas such as POCl₃, for 30 minutes at 900 to 1000° C. Such gettering will increase the diffusion length of the wafer. After formation of the heavily n-doped layer or layers, they can be removed by, for example, etching using acids such as hydrofluoric acid (HF) and nitric acid (HNO₃) or a mixture thereof, or strong bases such as sodium hydroxide (NaOH). One embodiment of this invention would involve forming a heavily n doped layer on the front of the wafer to getter impurities and then subsequently removing it during the texture etching of the front surface as described above.

In the preferred embodiment of this invention, a first passivation layer, preferably one that can also function as an anti-reflective coating, is formed on the front surface of the wafer. If the wafer is textured, such layer is preferably added after such texturing. Such first passivation layer can be, for example, a layer of a dielectric such as silicon dioxide, silicon oxynitride or silicon nitride, which can be formed by methods known in the art such as, for example, plasma enhanced chemical vapor deposition (PECVD), low pressure chemical vapor deposition (LPCVD), thermal oxidation, screen printing of pastes, inks or sol gel, and the like. Combinations of two or more of such layers can also be used to form the first passivation layer such as a layer of silicon nitride and a layer of silicon dioxide. When more than one layer is used, at least one of the layers is, preferably, an anti-reflective coating comprising, for example, silicon nitride. Preferably, such anti-reflective coating is added directly on the silicon wafer surface. Preferably, the first passivation layer comprises a layer of silicon nitride formed directly on the surface of the wafer. Each such layer used as an anti-reflective layer or as a first passivation layer or both, or the total of all such layers used, can be up to about 120 nm in thickness, for example about 70 to about 100 nm in thickness. The silicon nitride can be formed by, for example, PECVD or by LPCVD. A suitable method for applying the silicon nitride by LPCVD is to expose the wafer to an atmosphere of silicon compound, such as dichlorosilane, and ammonia at an elevated temperature of about 750° C. to about 850° C. Silicon nitride can also be deposited at lower temperatures of about 200° C. to about 450° C. using PECVD in an atmosphere of silane and ammonia.

A suitable first passivation layer can also comprise a layer of hydrogenated amorphous silicon (a- Si:H), a layer of hydrogenated microcrystalline silicon, or a mixture of a- Si:H and hydrogenated microcrystalline silicon, and particularly where such layer is deposited or otherwise formed so it is directly on the wafer. Preferably such layer comprises nitrogen in addition to silicon. Such layer can also comprise boron, with or without nitrogen. In some cases, it may be preferable for such layer to comprise other dopants such as phosphorus or be alloyed with other elements such as carbon, nitrogen or oxygen. If nitrogen is included in the first passivation layer comprising a- Si:H, hydrogenated microcrystalline silicon, or mixtures thereof, the amount or concentration of nitrogen can be graded such that the amount of nitrogen in the layer is at a minimum, for example, no nitrogen, next to the wafer, and reaches a level so that the layer becomes silicon nitride furthest away from the interface with the wafer. Ammonia or a mixture of hydrogen and nitrogen gas can be used as suitable sources of nitrogen. If boron or phosphorus is used, the boron or phosphorus concentration can be graded in the same manner where there is no boron or phosphorus next to or nearest to the wafer and reaching a maximum boron or phosphorus concentration up to about 1 atomic percent, based on the total amount of silicon and, if present, nitrogen in the layer. If such layer comprising a- Si:H, hydrogenated microcrystalline silicon, or mixtures thereof are applied, with or without nitrogen, and with or without a dopant such as boron or phosphorus, it can have a thickness of up to about 40 nm. It can, for example, be about 4 to about 30 nm thick. Such a- Si:H layer can be applied by any suitable method such as, for example, by PECVD in an atmosphere of silane. Most suitably, it is applied by PECVD in an atmosphere containing about 10% silane in hydrogen, and most suitably it is applied at low temperatures such as, for example, about 100° C. to about 250° C. Without intending to be bound by a theory of operation, the first passivation layer can function to reduce the wafer surface recombination velocity to <100 cm/s (a low surface recombination velocity (<100 cm/s) is indicative of a low density of defect states at the surface). The first passivation layer can also contain fixed charges, such as commonly found in silicon nitride layers, whose electric field induces band bending in the region of the semiconductor wafer near the wafer surface. Since the fixed charge in silicon nitride is usually positive, this band bending can act to repel minority carriers from the wafer surface region and can thus also reduce surface recombination if the wafer is n-type. If the wafer is p-type, the positive charge can act to create an accumulation layer, and the surface recombination can still be low if the density of defects on the surface is low. Thus, any material that can provide such function and can be applied to the silicon wafer, can be a suitable first passivation layer. Such layer, as described above, can comprise a plurality of layers, some or all of such layers being different materials selected, for example, from the materials described above.

In one embodiment, the first passivation layer comprises a layer of a- Si:H or hydrogenated microcrystalline silicon or a combination thereof deposited on the first surface of the wafer, and where such layer can have the structure or formulation as just described, followed by at least one layer of silicon nitride that acts as an anti-reflective layer. The thickness of the silicon nitride can be up to about 120 nm thick, for example about 70 to about 100 nm in thickness. The anti-reflective condition may be improved by the use of two layers of the appropriate thicknesses. Thus, for example, the passivation layer is a layer of a- Si:H, with or without nitrogen, and with or without boron or phosphorus, as described above, positioned directly on the first surface of the wafer followed by a layer of silicon nitride positioned directly on such a- Si:H layer and optionally followed by another, auxiliary layer, such as, for example, comprising tantalum oxide, silicon dioxide, magnesium fluoride, or titanium oxide, and the thicknesses of the silicon nitride and the auxiliary layer are chosen to optimize the anti-reflective condition. For example, the silicon nitride layer can have a thickness of about 70 nm to about 100 nm, and the auxiliary layer, for example, magnesium fluoride, can have a thickness of about 130 nm to about 200 nm.

In another embodiment, the silicon nitride layer can act both as the passivation layer and the anti-reflective layer on the first surface of the wafer with a thickness of up to about 120 nm thick, for example about 70 to about 100 nm in thickness. The silicon nitride can be deposited by PECVD in silane and ammonia at a deposition temperature of about 400° C.

In another embodiment, the nitrogen content of such silicon nitride layer is graded. For example, the nitrogen content can increase from zero at the part of the silicon nitride layer nearest the surface of the silicon wafer to approximately the level found in Si₃N₄ over a thickness of up to about 10 nm and then remains constant over the remaining thickness of the layer, for example, about another 70 nm.

During the step of depositing a passivation layer on the front surface of the wafer it is preferable to apply the layer or layers in a manner that prevents such layer or layers from forming on the back surface of the wafer. This can be accomplished by, for example, masking the back surface or placing the back surface in intimate contact with a substrate carrier. Nevertheless, the back surface of the wafer may also receive a layer of such coating covering all or part of the back surface. This layer on the back surface can be removed later by, for example, acid etching using an acid such as nitric or hydrofluoric acid, or mixtures thereof, or by etching with an aqueous solution of a strong base such as sodium hydroxide.

The back or second surface of the wafer in the photovoltaic cells of this invention comprises two electrical contacts, preferably each comprises one or more metals such as aluminum, copper, gold, silver, tin and the like, one for each polarity of electrical current produced by the cell. Although each such contact of a given polarity can comprise one or more sections electrically separated on the surface of the wafer, each such section of the same electrical polarity are preferably, at some point, electrically connected so maximum current can be produced from the photovoltaic cell. Such electrical contacts can be in the form of strips where, for example, the strips of one contact are interposed in spaces between strips forming the other contact producing an interposing or interdigitated pattern. The electrical separation between the two contacts should be small and the width of each contact, for example the width of each strip, should also be small. These electrical contacts can have a width of up to about 100 microns, for example, about 20 to about 80 microns. The spacing or separation between the contacts, that is, the gap between the electrical contact of one polarity and the electrical contact of the other polarity, can be up to about 30 microns, for example, about 5 to about 20 microns. The spacing or separation of the contacts, that is the spacing between the edge of the first electrical contact (the emitter contact) and the center of the second electrical contact (the base contact) is preferably less than the diffusion length of the minority carriers. In another embodiment, one of the electrical contacts, the first electrical contact, can be in the form of a first contact layer over the back surface of the photovoltaic cell, and the other can be in the form of point contacts where the point contacts extend from a second layer of electrical contact material positioned over the back surface of the photovoltaic cell and extending through an insulating layer between the first and second electrical contact layer. Although an electrical contact can, as will be described in greater detail below, comprise different layers or can comprise point contacts, at least a portion of the contact preferably comprises a conductive metal such as one or more of aluminum, copper, gold, silver, tin and the like. The metal layers that form the electrical contacts in the photovoltaic cells of this invention, can have a thickness of up to about 5 microns, for example, up to about 2 or 3 microns. Suitably, they can have a thickness of about 1 to about 2 microns. As described above, the electrical contacts in the photovoltaic cell of this invention are mainly, and preferably only, on the back surface of the wafer and therefore do not shade or obstruct the front, light-receiving surface of the wafer. This results in a photovoltaic cell that is more efficient in converting light energy to electrical energy.

The photovoltaic cell of this invention comprises a second passivation layer positioned over the back or second surface of the wafer and in a region that is at least between one of the electrical contacts and the second surface of the wafer. Thus, depending on the embodiment of the invention, such second passivation layer can be over most or all of the entire second surface of the wafer or it can be positioned, for example, only in the region between one or both of the electrical contacts and the second or back surface of the wafer. Without intending to be bound by a theory of operation, such second passivation layer reduces the density of defects at the second surface of the wafer. Thus, the second passivation layer can comprise one or more of a- Si:H, alloys of a- Si:H and carbon, alloys of a- Si:H and nitrogen, alloys of a- Si:H and oxygen, hydrogenated microcrystalline silicon, or mixtures of a- Si:H and hydrogenated microcrystalline silicon. The second passivation layer suitably comprises a- Si:H optionally having a hydrogenated microcrystalline silicon alloy present. The second passivation layer can be up to about 30 nm in thickness, for example, about 4 to about 10 nm thick. Any suitable method can be used to form the second passivation layer. Preferably it is formed on and in direct contact with the second surface of the wafer. For example, if the second passivation layer comprises a- Si:H, it can be applied using PECVD in silane at a temperature of up to about 250° C., for example about 100 to about 200° C.

The photovoltaic cell of this invention also comprises a layer of a semiconductor material having conductivity opposite that of the wafer, and where such semiconductor layer is positioned in the region between the second passivation layer and the first contact. The semiconductor layer can comprise any suitable material such as, for example, suitably doped, a- Si:H, hydrogenated microcrystalline silicon or mixtures thereof. When the silicon wafer is p-type, the semiconductor layer can comprise n- type, a- Si:H, hydrogenated microcrystalline silicon, or mixtures thereof. Phosphorus, arsenic, or antimony or mixtures thereof can, for example, be used as the dopant material. The total amount of such dopant can be about 0.01 atomic percent to about 1.0 atomic percent based on the total amount of dopant and silicon. Such semiconductor layer can be up to about 30 nm in thickness, for example, about 10 to about 20 nm in thickness. The semiconductor layer can be formed using any suitable method. If the layer comprises n-type a- Si:H, it can be applied using PECVD at a substrate temperature of about 200° C. in an atmosphere of silane containing a small amount of phosphine to provide the layer applied with the amount of phosphorus mentioned above. A photovoltaically active junction, for example a p-i-n or n-i-p junction preferably is formed between the silicon wafer having a first conductivity and the semiconductor layer having the opposite conductivity. If the wafer is n-type, such semiconductor layer can be p-type and can be formed by depositing boron-doped a-Si:H, hydrogenated microcrystalline silicon, or mixtures thereof, at a substrate temperature of about 200° C. using PECVD in an atmosphere containing about 1 volume percent of diborane in silane. The p-type semiconductor layer could also be formed using PECVD in an atmosphere containing about 1 volume percent of trimethlyaluminum.

The photovoltaic cells of this invention suitably comprise a transparent conductive oxide (TCO) layer positioned between at least one metal contact and the second passivation layer. Such TCO layer is preferably in direct contact with a metal component of the electrical contact and, preferably, is in direct contact with at least the layer of semiconductor material having conductivity opposite that of the wafer. Such TCO layer can comprise, for example, one or more of zinc oxide, tin oxide, or indium tin oxide. The TCO layer, whether comprising a single TCO layer or two or more layers, can have a thickness of up to about 120 nm, for example, about 70 to about 100 nm. Such TCO layer can be applied using any suitable method such as, for example, sputtering of ZnO from a sintered ZnO target at a substrate temperature of about 150° C.

Electrical contact can be made to the metal contacts on the back side of the wafer by attaching a bus bar or contact strip to the first metal contact along one edge of the wafer.

Certain embodiments of the invention will now be described with respect to the Figures. The Figures are not necessarily drawn to scale. For example, the thickness of the various metal, semiconductor and other layers shown in the Figures are not necessarily in scale with respect to each other.

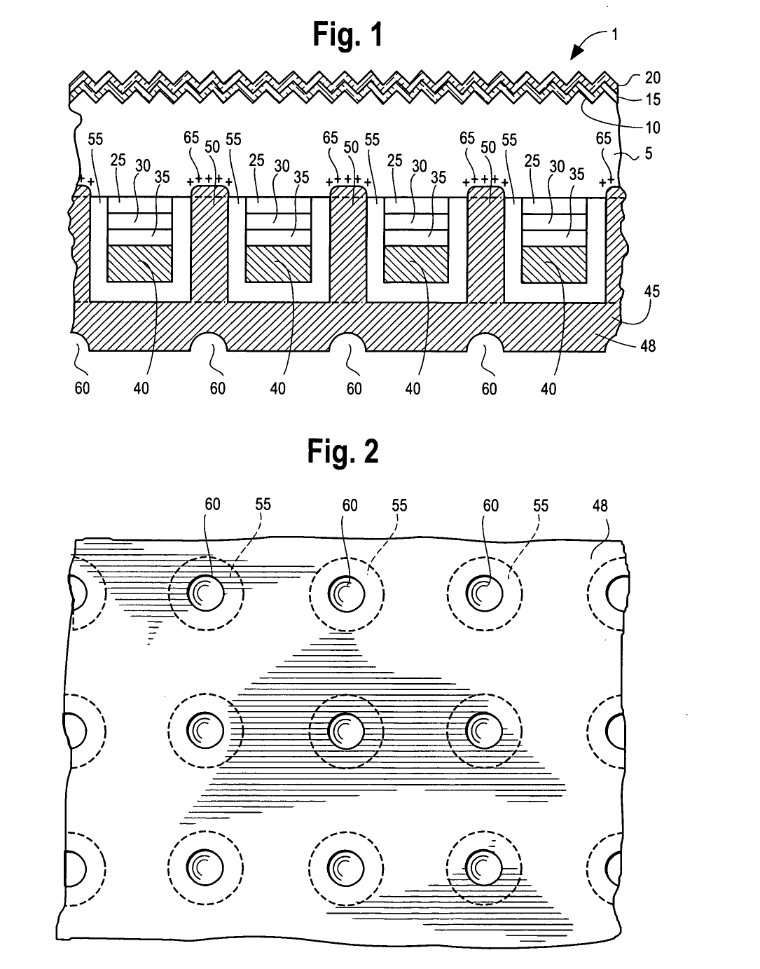

FIG. 1 shows a cross section of a part of photovoltaic cell 1 in accordance with an embodiment of this invention having point contacts. Photovoltaic cell 1 has wafer 5 of p-type crystalline silicon. Front or light receiving surface of wafer 5 is textured as shown by texture line 10. Wafer 5 has a first passivation layer on the front surface made of a layer of silicon dioxide 15 and a layer of silicon nitride 20. Photovoltaic cell 1 has a second passivation layer 25 comprising hydrogenated amorphous silicon (a-Si:H) and positioned in contact with wafer 5. Second passivation layer 25 is in contact with a layer 30 of n-type a- Si:H. Layer 30 is in contact with TCO layer 35 comprising indium tin oxide. TCO layer 35 is in contact with and positioned under first metal layer 40 comprising, for example, aluminum. Thus, first metal layer 40 together with TCO layer 35 forms the first electrical contact on the rear side of photovoltaic cell 1. FIG. 1 also shows second electrical contact 45 comprising a first portion 48 that is in the form of a layer over the back surface of the wafer and second portions 50 which are point contacts that extend from the layer portion 48 into the wafer 5. Second electrical contact 45 can comprise, for example, a metal such as aluminum.

FIG. 1, shows insulation layer 55 comprising, for example, silicon nitride, positioned between second electrical contact 45 and layers 25, 30, 35 and first metal layer 40. Thus, insulation layer 55 separates and electrically insulates second electrical back contact 45 from the other electrical contact 40 and layers 25, 30 and 35. FIG. 1 also shows depressions or dimple marks 60 in second electrical contact 45. As will be described in detail below, these depressions or dimples can be formed when second electrical contact layer 48 is “fired through” using, for example, a laser to form point contact portions 50 of second electrical contact 45 that extend into wafer 5. Thus, second electrical contact 45 is layer 48 and point contacts 50. FIG. 1 also shows back surface field (BSF) 65 located along the region where point contacts 50 of second electrical contact 45 meet or enter wafer 5. This BSF is represented in FIG. 1 as a collection of “+” signs. As will be discussed in more detail below, such BSF can be formed when the point contacts 50 are formed by, for example, using a laser to fire the metal layer 48 through to the wafer. The high temperature metal in contact 45 formed as a result of being heated by a laser beam forms the BSF when the high temperature metal comes in contact with the wafer 5. FIG. 2 is a plan view of part of the same photovoltaic cell shown in FIG. 1 looking onto the back surface of the photovoltaic cell. It shows that the point contacts can be in the form of an array pattern on the back of the photovoltaic cell. FIG. 2 shows dimples 60 (only a few numbered for clarity) and it also shows, as broken lines, the regions where the first metal layer 40 and its associated layers 25, 30, 35 are removed, for example, by laser ablating, before depositing the insulating layer 55, which fills the regions removed by, for example, the laser ablation. The removal of such layers will be described in more detail below. The point contact regions 50 (see FIG. 1) are formed by “firing through” with, for example, a laser in the center portion of the region of the second electrical contact that is above the region where first metal layer and its associated layers 25, 30 and 35 are removed. Metal layers described herein, such as metal layers 40 and 48 can be formed by, for example, magnetron sputtering a metal target such as an aluminum target when the metal layer is aluminum.

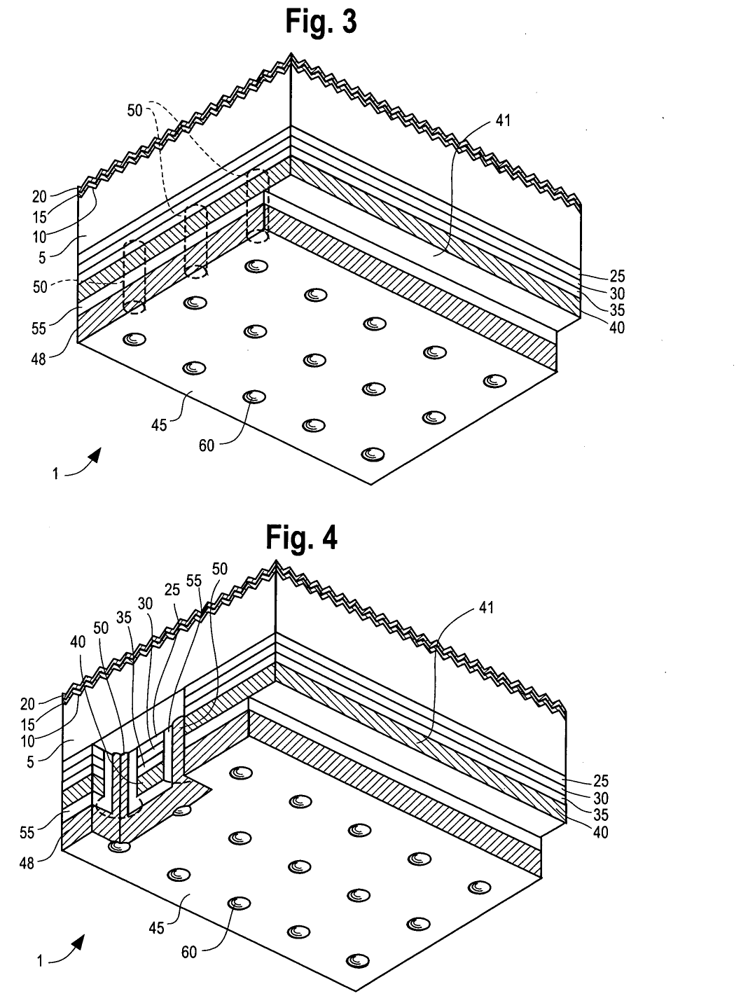

FIG. 3 shows in a perspective view a segment of a photovoltaic cell in accordance with an embodiment of this invention. All components of cell 1 in FIG. 3 that correspond to the same components in FIGS. 1 and 2 are numbered the same. For simplicity, only one dimple or depression 60 is labeled in FIG. 3 and only one point contact 50 is labeled. FIG. 3 shows clearly how point contacts 50 extend from metal layer 48 of the second electrical contact 45 through insulation layer 55 and enter wafer 5. For clarity, only a few point contacts depicted as dotted lines are shown in FIG. 3. FIG. 3 also shows, in three-dimensional representation, the array of point contacts that make up the second contact 45 which comprises metal layer 48 and a plurality of point contacts 50. FIG. 3 also shows how the first contact comprising metal layer 40 is electrically separated from second contact 45 comprising layer 48 and point contacts 50, and where such electrical separation is provided by insulating layer 55.

As shown in FIG. 3, one edge of the photovoltaic cell has a portion 41 of first metal contact layer 40 exposed. Such exposed portion can be used to connect a wire or other electrical conduit to the photovoltaic cell. Such exposed portion can be formed, for example, by removing layers 48 and 55 in FIG. 1, or such portion can be masked after the application of first metal contact layer 40 so that layers 55 and 48 are not formed thereon, and the mask thereafter removed to expose the contact.

FIG. 4 is the same as FIG. 3 except FIG. 4 shows in three-dimensional, partial cut-away view what point contacts 50 look like as they extend through the layers on the back of the photovoltaic cell. All components in FIG. 4 that are the same in FIG. 3 are numbered the same. Specifically, FIG. 4 shows how point contacts 50 under dimples 60 extend through first contact metal layer 40, TCO layer 35, n-type a- Si:H layer 30, second passivation layer 25 and into the silicon wafer 5. FIG. 4 also shows how insulating layer 55 is next to and surrounds point contacts 50. Insulation layer 55 thus electrically insulates first contact layer 40 from point contacts 50.

Without intending to be bound by a theory of operation, the first metal contact 40 and its associated layers 25, 30, and 35 collect photogenerated electrons (for a p-type wafer 5) and the point contacts 50 collect photogenerated holes. The photogenerated electrons and holes are created when light is incident on the front surface 10 and is absorbed in the crystalline silicon wafer 5. The wafer 5, the passivation layer 25 and the n-type a- Si:H layer 30, form a p-i-n semiconductor junction with a built-in electric field that helps to collect the photogenerated electrons. The point contacts 50 form an ohmic contact to the p-type wafer 5 that efficiently collects the photogenerated holes.

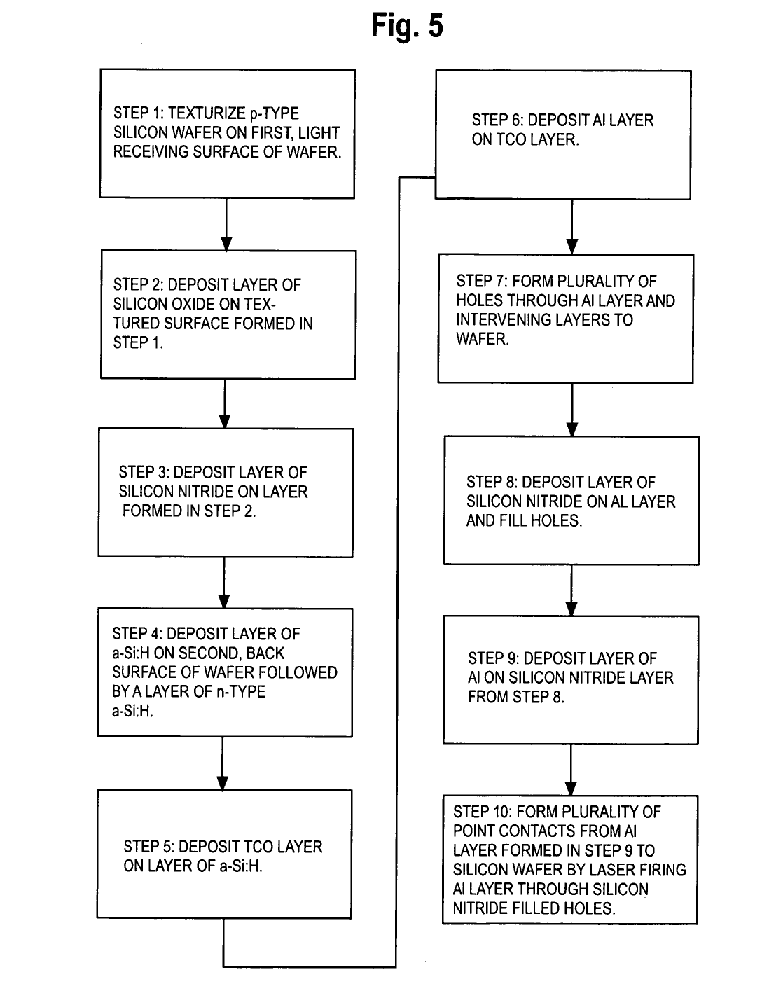

A process for manufacturing a photovoltaic cell in accordance with this invention and having a structure as shown in FIGS. 1 through 3 will now be described, it being understood that this is not the only process for preparing such photovoltaic cell. The process is also shown in block diagram form in FIG. 5.

In Step 1 a silicon wafer suitable for the manufacture of photovoltaic cells, doped with boron (referred to as p-type) having a thickness of about 200 microns is texturized on a first side or face of the wafer that will eventually be the light receiving side of the photovoltaic cell made from the wafer. The texturing may be performed by etching in an appropriate acidic or basic solution, by well-known processes. The back surface of the wafer may or may not be textured depending on the thickness of the wafer and the light-trapping geometry employed. In Step 2, a thin layer of silicon oxide is grown on the textured surface by a thermal oxidation process, which may be accomplished, for example by heating the wafer for several minutes at a temperature in the range of 850 to 900° C. in an atmosphere containing oxygen and hydrogen. The conditions for this process may be chosen so that the silicon oxide layers is about 5-20 nm thick. In Step 3, a layer of silicon nitride is deposited on top of the silicon oxide layer using plasma-enhanced chemical vapor deposition (PECVD) in an atmosphere of silane and ammonia at a temperature of about 400° C. The layer is about 60 to about 90 nm thick, depending on the thickness of the silicon oxide layer. The thicknesses of the silicon oxide layer and the silicon nitride layer are chosen to maximize the light transmission into the photovoltaic cell. In another embodiment, the thin oxide layer can be omitted and a layer of silicon nitride is deposited directly onto the textured, first side of the wafer. This layer is about 80 nm thick and may be graded so that the nitrogen content increases from zero at the surface of the silicon oxide to approximately the level found in Si₃N₄ over a distance of about 10 nm and then remains constant over a distance of about 70 nm. If no silicon oxide layer is added, the grading would start at the first surface of the wafer. The back surface of the wafer is protected from receiving such layer by having the wafer in intimate contact with the substrate holder. In Step 4 a layer of a- Si:H about 5 nm thick is added directly to the back surface of the wafer using PECVD in silane at a temperature of about 200° C. with the front surface in intimate contact with the wafer holder or otherwise shielded from the silane plasma to prevent deposition of a-Si:H on the front surface, followed immediately by adding a layer of n-type a- Si:H about 20 nm thick. The layer of n-type a- Si:H can be applied to the layer of intrinsic a- Si:H by adding the proper amount of n-dopant, such as phosphine, to the gas mixture of silane and hydrogen used to apply the intrinsic layer during the PECVD process. Thus, the addition of the layer of a- Si:H to the p-type wafer followed by the addition of the n-type layer of a- Si:H establishes a photovoltaically active p-i-n junction on the back surface of the wafer. While described and exemplified herein as two distinct layers, it is to be understood that the boundary between the intrinsic layer of a- Si:H and the n-type a- Si:H is not necessarily a distinct boundary and can, for example, be in the form of a graded boundary where the amount of n-dopant changes between layers gradually rather than abruptly as if it were two layers with a well defined boundary line. In Step 5 a layer of a transparent conductive oxide (TCO), such as indium tin oxide or zinc oxide is applied to the n-type, a- Si:H layer. The TCO layer may be zinc oxide about 80 nm thick and is conveniently applied using magnetron sputtering of a sintered zinc oxide target at a temperature of about 150° C. The TCO layer is, however, optional. In Step 6 a layer of metal, for example, aluminum about 1 micron thick is applied to the TCO layer using magnetron sputtering from an aluminum target in an argon atmosphere. This aluminum layer is the first electrical contact. In Step 7, a plurality of first holes are formed in the back of the wafer at least through the aluminum layer and, if present, the TCO layer. Preferably, such holes extend through all other layers to the surface of the silicon wafer and even into the wafer somewhat. The holes can be about 5 microns to about 50 microns in diameter and they are spaced so that the center of each hole is about 100 microns to 1 mm from the center of all adjacent holes. Preferably, the relationship of the wafer diffusion length to the diameter of the holes is such that the diffusion length should be greater than the diameter of the holes. The pattern of such holes is conveniently an array of columns and rows of holes. For example, for a wafer that is about 200 microns thick, the preferred spacing of the holes is such that there are about 64 holes per cm² to about 6400 holes per cm² or about 104 to 106 holes in a wafer having a surface area of 156 square centimeters. Preferably, the spacing of the holes is adjusted to minimize the series resistance of the photovoltaic cell and to maximize the performance. The holes can be made in any convenient manner such as by a mechanical drilling or by masking and then etching with a suitable etchant. However, a suitable method is to use a laser to form the holes. For example, an excimer laser can be used to ablate both the aluminum and TCO layers to form the desired sized holes. In Step 8 a layer of silicon nitride insulation is applied to the aluminum layer and into the holes that were formed in Step 7. The silicon nitride layer is about 100 nm thick and can be applied using magnetron sputtering at a substrate temperature of about 150° C. or PECVD at a substrate temperature of about 250° C. The silicon nitride may be made somewhat thicker than 100 nm, for example, 200 nm, depending on the deposition conditions to prevent leakage or shorting between the first and second electrical contacts. Although silicon nitride is used in this example as an insulation layer, other materials can be used in this invention as an insulation layer such as, for example, silicon oxynitride or silicon oxide. In Step 9, a second metal layer of, for example, aluminum is applied to the layer of silicon nitride to form the second electrical contact. The aluminum layer is about 1 micron thick and can be applied using magnetron sputtering. In Step 10, the second metal layer of, for example, aluminum is treated to form point contacts that extend from the second metal layer to the surface, and preferably into the surface, of the silicon wafer. Such point contacts can be formed by, for example, positioning a laser beam on the second metal layer at the locations in the central region of where the holes were formed in Step 7. The laser beam heats the metal in the second contact layer and the molten metal melts through the layer of silicon nitride (and any layers of amorphous silicon if the holes formed in Step 7 did not extend to the wafer), and into the wafer, leaving a layer of silicon nitride insulation material around the point contact. Since the point contacts are formed within the holes, the center of a point contact is about 100 microns to about 1 mm from the center of the point contacts immediately adjacent to it. Preferably, the spacing of the point contacts is adjusted to minimize the series resistance of the photovoltaic cell and to maximize photovoltaic cell performance. Additionally, due to the high temperature of the molten aluminum, it is preferable to carry out such procedures so that some of the aluminum diffuses into the silicon wafer forming a back surface field (“BSF”) in the wafer adjacent to where the aluminum metal contacts the wafer. While it is preferable to use a laser to form such point contacts, other methods can be used such as electron or ion beam bombardment of the aluminum layer in vacuum where the electron or ion beam is localized in the central regions where the holes were formed in Step 7. Other metals instead of or in addition to aluminum can be used, such as one or more of the metals described herein for forming electrical contacts.

Although the point contacts are shown as cylindrically shaped shafts or columns having a circular horizontal cross-sectional shape, it is to be understood that such point contacts can be any suitable shape. For example, instead of round holes filled with electrical contact material, such point contacts can be hemispherical, or shafts or columns with an oval or more elongated cross-sectional shape, or any other suitable geometric shape or pattern. The width of the point contact, for example, the diameter of a cylindrically or column-shaped point contact, or the width of a point contact having an oval or more elongated cross-sectional shape, can be up to about 100 microns, for example, about 5 to about 100 microns.

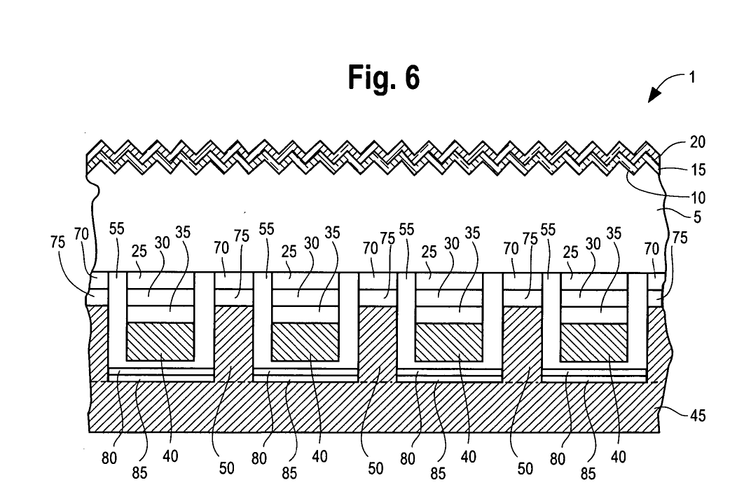

FIG. 6 shows a cross section of a part of photovoltaic cell 1 in accordance with an embodiment of this invention having point contacts where the point contacts are passivated. That is, there is a passivation layer or layers between the metal portion of the point contact and the second surface of the wafer. The elements of the photovoltaic cell in FIG. 6 that are the same as the elements in FIG. 1 are numbered the same. As shown in FIG. 6, between the point contacts 50 and wafer 5 are layers 70 and 75. In addition, due to the way the photovoltaic cell 1 in FIG. 6 is made, which will be described below, layers 80 and 85 are positioned between insulating layer 55 and second electrical contact 45. Layers 80 and 85 have the same composition, at least when initially deposited, as layers 70 and 75, respectively. For example, point contact passivation layer 70 can comprise one or more of a- Si:H, alloys of a- Si:H and carbon, alloys of a- Si:H and nitrogen, alloys of a- Si:H and oxygen, hydrogenated microcrystalline silicon, or mixtures of a- Si:H and hydrogenated microcrystalline silicon. It suitably comprises a- Si:H optionally having a hydrogenated microcrystalline silicon alloy present. The point contact passivation layer can be up to about 30 nm in thickness, for example, about 4 to about 10 nm thick. Any suitable method can be used to form the point contact passivation layer. Preferably it is formed on and in direct contact with the second surface of the wafer 5. For example, if the point contact passivation layer comprises a- Si:H, it can be applied using PECVD in silane at a temperature of up to about 250° C., for example about 100 to about 200° C.

The photovoltaic cell of this invention as shown in FIG. 6 also comprises a point contact doped semiconductor layer having conductivity the same as that of the wafer, and where such point contact doped semiconductor layer 75 is positioned in the region between the point contact passivation layer 70 and the point contact 50. This point contact doped semiconductor layer can comprise any suitable material such as, for example, suitably doped, a- Si:H, hydrogenated microcrystalline silicon or mixtures thereof. If the wafer 5 is p-type, the point contact doped semiconductor layer can comprise p-type, a- Si:H, alloys of p-type a-Si:H and carbon, alloys of p-type a-Si:H and nitrogen, or alloys of a-Si:H and oxygen or mixtures thereof. Boron can, for example, be used as the p-type dopant material. The total amount of such dopant can be about 0.01 atomic percent to about 1.0 atomic percent based on the total amount of silicon, alloying material and dopant present. Such point contact doped semiconductor layer can be up to about 30 nm in thickness, for example, about 10 to about 20 nm in thickness. The point contact doped semiconductor layer 75 can be formed using any suitable method. If the layer comprises p-type a- Si:H, it can be applied using PECVD at a substrate temperature of about 200° C. in an atmosphere of silane containing a small amount of diborane to provide the layer applied with the amount of boron dopant mentioned above. If the wafer 5 is n-type, then the point contact doped semiconductor layer can comprise n-type a-Si:H, alloys of a-Si:H and carbon, alloys of a-Si:H and nitrogen, or alloys of a-Si:H and oxygen or mixtures thereof. Phosphorus can, for example, be used as the n-type dopant material. The total amount of such dopant can be about 0.01 atomic percent to about 1.0 atomic percent based on the total amount of silicon, alloying material and dopant present. Such point contact doped semiconductor layer can be up to about 30 nm in thickness, for example, about 10 to about 20 nm in thickness. The point contact doped semiconductor layer 75 can be formed using any suitable method. If the layer comprises n-type a- Si:H, it can be applied using PECVD at a substrate temperature of about 200° C. in an atmosphere of silane containing a small amount of phosphine to provide the layer applied with the amount of phosphorus dopant mentioned above.

The photovoltaic cell 1 in FIG. 6 can, for example, be made in the same manner as descried for the photovoltaic cell 1 of FIG. 1 except after the step of depositing insulation layer 55, a second step can be used to make second holes in the central region of the first holes. These second holes are made so that the surface of the wafer is exposed. The second holes can be made by any suitable method as, for example, by laser ablation using an Nd-YAG-laser with a laser beam energy density sufficient to ablate the insulating layer 55. The point contact passivation layer 70 is deposited in the second holes by the methods described above, and can be deposited on the entire outer surface of the insulating layer 55 thus forming layer 80. After depositing point contact passivation layer 70, the point contact doped semiconductor layer 75 can be deposited by one or more methods described above. Again, such layer is deposited in the second holes over the point contact passivation layer to form layer 75 and can be deposited over the entire surface of the insulation layer 55 to form layer 85. The metal layer 45, for example, aluminum, is deposited next to form the second electrical contact. The metal layer can be deposited by one or more of the same methods described above for the deposition of layer 45 in FIG. 1. When such metal layer is deposited, it fills the holes having the point contact passivation layer 70 and the point contact doped semiconductor layer 75 to complete the passivated point contact for the photovoltaic cell. Metal layer 45 can be about 1 micron to about 2 microns in thickness. Although not shown in FIG. 6, between the metal portion of point contacts 50 and point contact semiconductor layer 75, a layer of TCO can be added. Such TCO layer can comprise, for example, one or more of zinc oxide, or tin oxide, indium tin oxide. The TCO layer, whether comprising a single TCO layer or two or more layers, can have a thickness of up to about 120 nm, for example, about 70 to about 100 nm. Such TCO layer can be applied using any suitable method such as, for example, sputtering of ZnO from a sintered ZnO target at a substrate temperature of about 150° C.

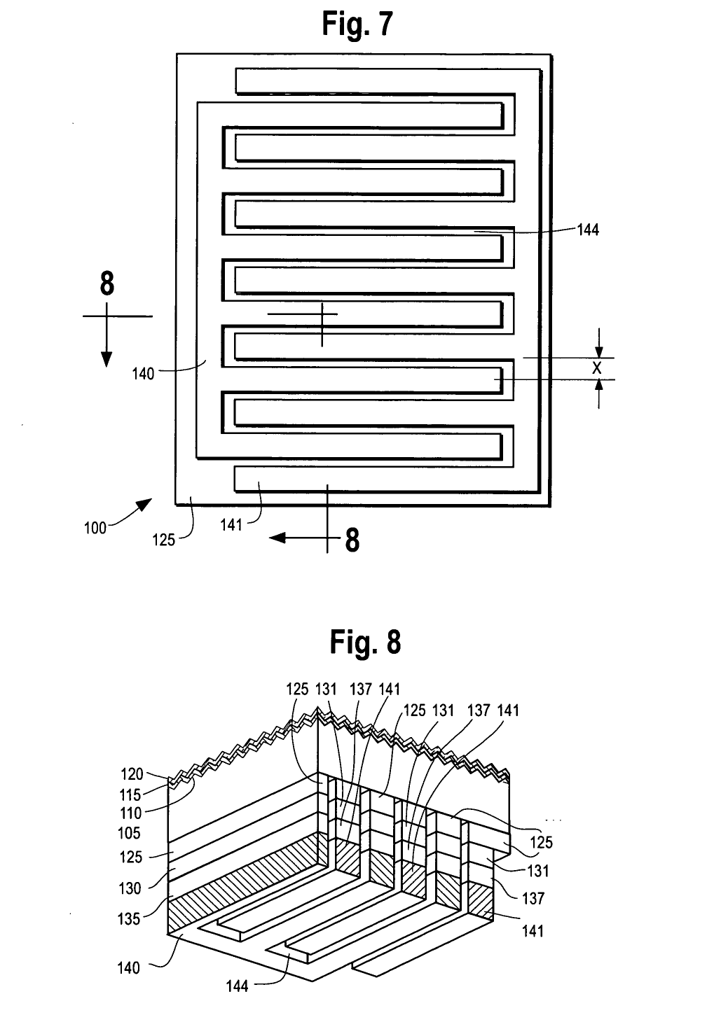

FIG. 7 shows a plan view of the back of photovoltaic cell 100 in accordance with another embodiment of this invention having interdigitated electrical contacts on the back surface of the cell. FIG. 7 shows first electrical contact 140 and second electrical contact 141. As described in more detail below, 140 and 141 are electrical contacts having an interdigitated structure. As shown in FIG. 7, the electrical contacts 140 and 141 are in a form of interdigitated “fingers” so that each contact is closely spaced from the other contact and electrically separated by space 144. As described above, the electrical separation 144 is, preferably, up to about 30 microns; for example, about 5 to about 20 microns. Each “finger” in the electrical contact can be up to about 100 microns wide; for example, about 20 to about 80 microns wide. FIG. 7 also shows passivation layer 125 which is described in more detail below. It is to be understood that FIG. 7 is a simplified view of the interdigitated contacts. In an actual photovoltaic cell, preferably, the number of “fingers” used would depend on the size of the wafer and would be selected to achieve an optimized cell efficiency. Thus, the number of fingers in the functioning cell will, preferably, be many times more than the number of fingers shown in FIG. 7 and would, preferably, have a width and spacing the same as the ranges described above. For optimal photovoltaic cell performance the minority carrier diffusion length of the wafer should be greater than the spacing 144 and half the width of a finger nearest the space 144. This is shown more clearly in FIG. 7 where the distance “x”, which is the distance between a finger of a second contact (base contact) and a finger of a first contact (emitter contact) plus half the width of the finger of the first contact. The distance “x” is preferably less than the diffusion length of the wafer 105.

FIG. 8 is a three dimensional cross-sectional view of a portion of the photovoltaic cell 100 shown in FIG. 7. It is the portion viewed as shown in FIG. 7 as 8. The front or light receiving surface of p-type wafer 105 is textured as shown by texture line 110. Wafer 105 has a first passivation layer 115 on the front surface made of a layer of silicon dioxide and a layer of silicon nitride 120. Photovoltaic cell 100 has a second passivation layer 125 comprising hydrogenated amorphous silicon and positioned in contact with wafer 105. Second passivation layer 125 is in contact with a layer 130 of n-type a- Si:H. Layer 130 is in contact with TCO layer 135 comprising zinc oxide or indium tin oxide. TCO layer 135 is next to, in contact with, and positioned under first metal layer 140 comprising, for example, aluminum. Thus, aluminum metal layer 140 together with TCO layer 135 forms the first electrical contact on the rear side of photovoltaic cell 110. FIG. 100 also shows second electrical contact 141 comprising a layer 131 comprising p-type a- Si:H and a TCO layer 137 comprising, for example, tin oxide or indium tin oxide. While layers 115, 120, 125, 130, 131, 135, 137, 140, 141 have been described herein, it is to be understood that they can comprise other materials and be made as described for the corresponding layers as described above for the other embodiments of this invention. For example, they can have the composition and dimensions of the corresponding layers as described for the photovoltaic cell shown in FIGS. 1-4. In particular, layer 115 can comprise a- Si:H and if carbon is included in this layer of a- Si:H, the amount of carbon can be graded such that the amount of carbon in the a- Si:H is at a minimum, for example, no carbon, next to the wafer, and at a maximum, for example, about 15, 20 or 25 atomic percent (based on total of silicon and carbon atoms in the layer) furthest away from the interface between the wafer and the a- Si:H layer. If boron is included in the layer, the boron concentration can be graded in the same manner where the maximum boron concentration is about 1 atomic percent (based on the total amount of silicon, boron and, if present, carbon in the layer.) The photovoltaic cell shown in FIGS. 7 and 8 can be made by texturing the wafer using one or more of the texturing methods described above. Layers 115 and 120 can be deposited by PECVD. Layer 115 comprising, for example a- Si:H containing carbon where the carbon is graded, as described above, can be deposited at a substrate temperature of about 150 to about 300° C. using a plasma in silane and hydrogen, and gradually increasing the amount of methane and, if desired borane, in the gas mixture to achieve a desired grading of carbon and/or boron in the layer. If the wafer is an n-type crystalline silicon wafer, then phosphine or other source of phosphorus, or other n-dopant, can be used in the silane gas feed to form a graded a- Si:H layer 115 containing phosphorus or other n -type dopant instead of carbon or boron. The levels of phosphorous, or other n-type dopant, grading can be the same as that for boron. In forming the back contact, the second passivation layer 125 comprising, for example, a- Si:H, can be applied over the entire back surface of the wafer using, for example, PECVD, at a substrate temperature, for example, of about 150 to about 250° C. After depositing layer 125, layer 130 can be applied comprising, for example, n-type a- Si:H, over the entire back surface of the wafer at a temperature of, for example, about 150 to about 250° C. Next a CTO layer 135, comprising, for example, zinc oxide or indium tin oxide, is deposited by, for example, sputtering. Next, metal layer 140, comprising, for example, aluminum, is deposited by, for example, sputtering. The next step is to form the spacing 144 for the interdigitated contacts. This can be accomplished by removing layers 125, 130, 135 and 140 in the desired pattern such as, the pattern shown in FIG. 7, for spaces 144. Such layers can be removed by any suitable method, such as for example masking and chemical etching. However, a preferred method is to use a laser, such as a high speed scanning layer, to ablate the layers in the desired pattern. For example, a frequency-doubled Nd-Yag laser can be used to ablate the deposited layers in the appropriate regions. Preferably, the laser should remove the layers 125, 130, 135 and 140 in the desired pattern without damaging the surface of wafer 105. After such laser ablation step, the surface of the wafer exposed can be treated with a hydrogen plasma discharge to ameliorate or repair damage that may have been caused by the laser to the wafer surface.

After such step to remove the layers, a layer 125 of, for example, a- Si:H is added, then layer 131, which can comprise, for example, p-type a- Si:H, is added then TCO layer 137 comprising, for example, indium tin oxide or zinc oxide, followed by metal layer 141 comprising, for example, aluminum. These layers will fill the spaces formed in the previous step by laser ablation or other method used to remove layers 125, 130, 135 and 140. A layer 125 of a-Si:H and layers 131 and 137 will also form on top of layer 140. However, when metal layer 141 is applied, it reacts with the amorphous silicon layers a-Si:H and p-type a- Si:H to form a conductive eutectic.

In order to complete the interdigitated back contact, a gap or space 144 is formed between layers 140 and 141. The gap or space can be formed by any suitable method. However, the preferred method is to use a laser to remove the layers between 140 and 141. For example, a frequency-doubled Nd-Yag laser can be used to ablate the deposited layers in the appropriate regions. In an optional step, after the formation of the gap or space, the back surface of the wafer is treated to form a passivation layer comprising one or more of the materials used to form layer 125. Such passivation layer passivates the portion of the wafer exposed by the step used to form the gap or space 144. Such layer is not shown in FIG. 8. It can have the same thickness as described for layer 125 and, as mentioned above, and can have the same composition.

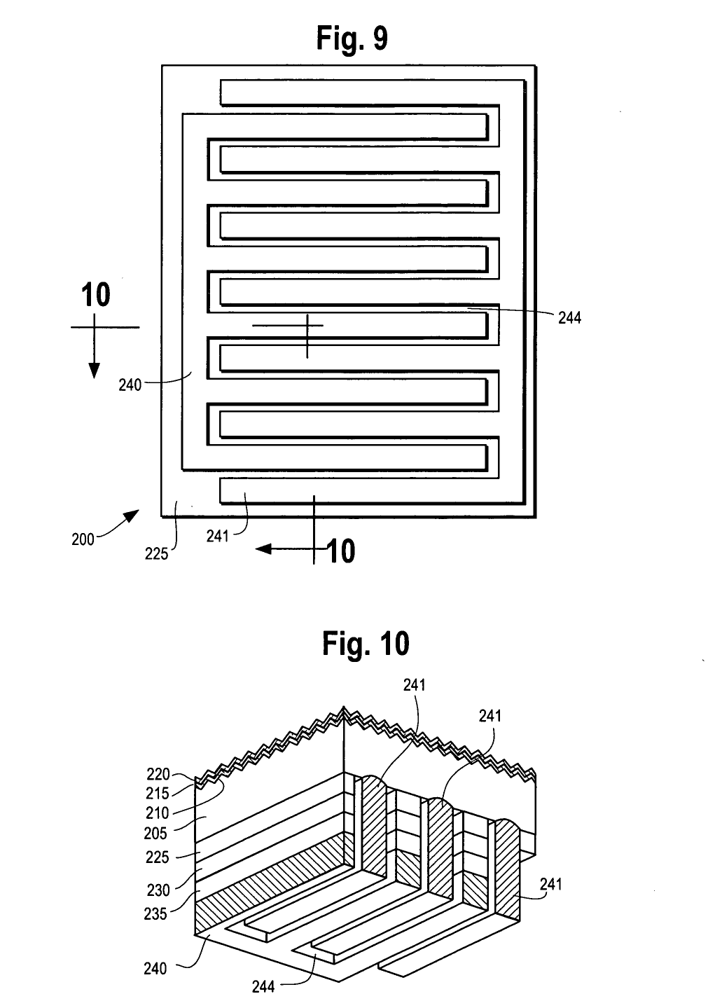

FIG. 9 shows a plan view of the back of photovoltaic cell 200 in accordance with another embodiment of this invention having interdigitated electrical contacts on the back surface of the cell. However, in this embodiment, one contact on the back surface of the cell, contact shown in FIG. 9 as 241, comprises metal, such as aluminum, that can be deposited, for example, initially as an aluminum-containing paste, followed by firing the paste at a temperature and for a time sufficient to form an aluminum contact in the desired finger pattern as shown. Again, like FIG. 7, FIG. 9, for simplicity, shows only a few “fingers”. The actual cell will likely have a large number of fingers to achieve the desired spacing and maximum charge collection capabilities. FIG. 9 also shows other electrical contact 240 and a- Si:H layer 225. Contacts 240 and 241 form an interdigitated pattern separated by space or gap 244 as described above for the cell shown in FIG. 7. The spacing and width of such fingers can be as described above for FIGS. 7 and 8.

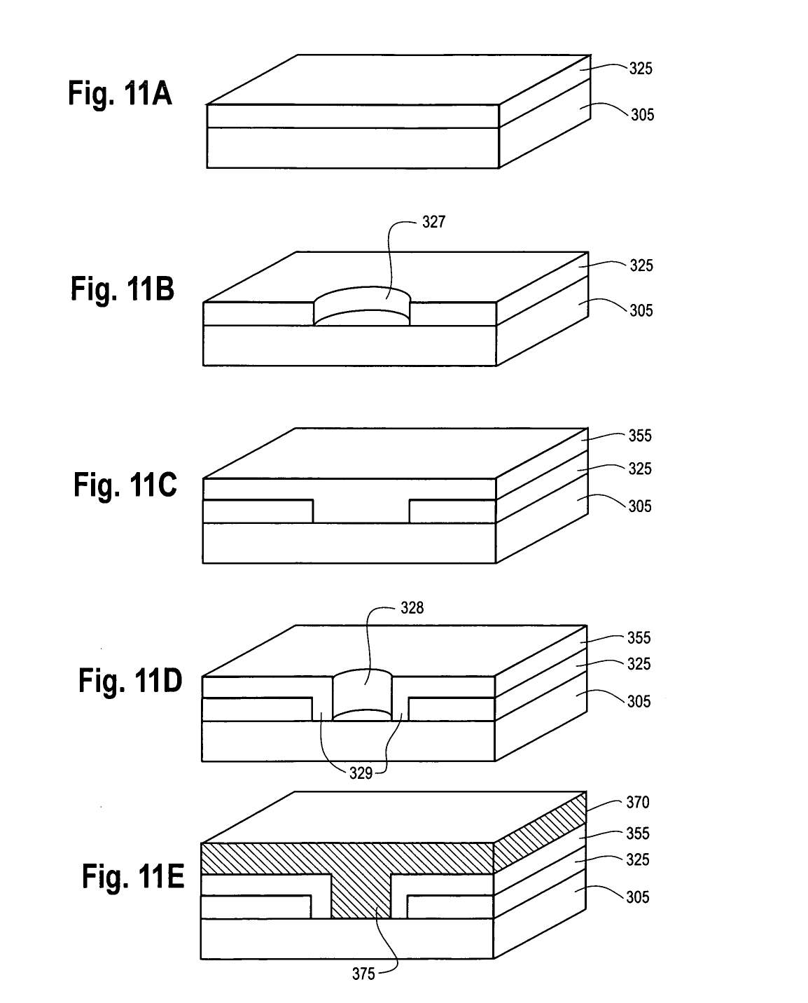

FIG. 10 is a three dimensional cross-sectional view of a portion of the photovoltaic cell 200 shown in FIG. 9. It is the portion viewed as shown in FIG. 9 as 10. The front or light receiving surface of wafer 205 is textured as shown by texture line 210. Wafer 205 having, for example, p-type conductivity, has a first passivation layer 215 on the front surface comprising, for example, a layer of silicon dioxide, and a layer of silicon nitride 220. Photovoltaic cell 200 has a second passivation layer 225 comprising, for example, hydrogenated amorphous silicon and positioned in contact with wafer 205. Second passivation layer 225 is in contact with a layer 230 comprising n-type a- Si:H. Layer 230 is in contact with TCO layer 235 comprising, for example, zinc oxide or indium tin oxide. TCO layer 235 is next to, in contact with, and positioned under first metal layer 240 comprising, for example, aluminum. Thus, metal layer 240 together with TCO layer 235 forms the first electrical contact on the rear side of photovoltaic cell 210. FIG. 200 also shows second electrical contact 241 comprising, for example, aluminum that can be applied to the wafer 205, as described above. Layers 215, 220, 225, 230, 235, 240 and 241 can comprise the materials and be made as described for the corresponding layers as described above for the other embodiments of this invention. For example, they can have the composition and dimensions of the corresponding layers as described for the photovoltaic cell shown in FIGS. 14. In particular, layer 215 can comprise a- Si:H and if carbon is included in the layer of a- Si:H, the amount of carbon can be graded such that the amount of carbon in the a- Si:H is at a minimum, for example, no carbon, next to the wafer, and at a maximum, for example, about 15, 20 or 25 atomic percent (based on total of silicon and carbon atoms in the layer) furthest away from the interface between the wafer and the a- Si:H layer. If boron is included in the layer, the boron concentration can be graded in the same manner where the maximum boron concentration is about 1 atomic percent (based on the total amount of silicon and, if present, carbon in the layer. Electrical contact 240 and 244 can have the spacing and gap dimensions as described for the cell shown in FIGS. 7 and 8.

The photovoltaic cell shown in FIGS. 9 and 10 can be made in the same manner as described above for the cell shown in FIGS. 7 and 8 except that the layers 225, 230, 235 and 240 are preferably formed after the metal contact 241 is formed. The laser is then used to form space or gap 244 by ablating layers 225, 230, 235 and 240 in the desired pattern to form the electrically separated, interdigitated contacts 240 and 241.

This invention is also a method for making an electrical contact from an electrical conductor layer such as metal layer, to a second layer in a semiconductor device, wherein the electrical conductor layer is separated from the second layer by at least a third layer and where the third layer is, preferably, an electrically insulating layer. For example, the second layer can be a wafer, such a crystalline or multicrystalline silicon wafer, as described herein, the electrically insulating layer can be, for example, one or more of a layer of silicon nitride, silicon dioxide, or silicon oxynitride. Preferably, the electrically insulating layer comprises silicon nitride. There can be other layers such as, for example, one or more of a- Si:H, alloys of a- Si:H and carbon, alloys of a- Si:H and nitrogen, alloys of a- Si:H and oxygen, hydrogenated microcrystalline silicon, or mixtures of a- Si:H and hydrogenated microcrystalline silicon, a metal layer, and p- or n-doped a-Si:H. Where there are one or more layers, such as one or more of a- Si:H, alloys of a- Si:H and carbon, alloys of a- Si:H and nitrogen, alloys of a- Si:H and oxygen, hydrogenated microcrystalline silicon, mixtures of a- Si:H and hydrogenated microcrystalline silicon, another metal layer, or p- or n-doped a-Si:H present on a wafer such as, for example, a silicon multicrystalline or crystalline wafer, described herein, the electrical contact can be made by the process comprising making a first hole or opening in the layer or layers using any suitable means for forming such hole or opening, so that the hole or opening preferably extends to the surface of the second layer. Preferably, a laser is used to form such hole or opening such as the lasers described hereinabove. The electrically insulating layer, such as for example, silicon nitride, is deposited on the top most layer and into the first holes or openings using, for example, the methods described herein. The process to form the contact can be completed by either of two different process sequences.

In one sequence, a second hole or opening is made through the insulation layer in the first hole or opening, preferably extending to the surface of the second layer, by any suitable method for forming such hole or opening and, preferably, by using a laser such as the lasers described herein. The second hole or opening is sized smaller than the first hole or opening so that a layer or region of insulation material remains around the inside surface of the second hole or opening. An electrical conducting layer, such as a metal layer, for example, one or more of the metal layers described herein, is deposited over the insulation layer and into the second hole thus forming the contact between the electrical conducting layer and the second layer.

The formation of an electrical contact made by the method described above using the first sequence is shown in schematic form in FIG. 11 using a silicon wafer as the second layer, a-Si:H as a layer between the electrical contact layer and the wafer, and silicon nitride as the insulation layer. FIG. 11 shows cross-section views of the electrical contact. It described using a metal as the electrical conducting layer. However it is to be understood that the electrical conducting layer can comprise other electrically conducting materials.

FIG. 11A shows wafer 305 having an a-Si:H layer 325 deposited thereon. As shown in FIG. 11B, first hole 327 is formed in layer 325 by one or more suitable methods such as by laser ablation of the layer. Thereafter a layer 355 of electrically insulating material, for example, silicon nitride, is deposited over layer 325 and into hole 327 as shown in FIG. 11C. Second hole 328 is formed in layer 355 in the center portion of what was first hole 327 as shown in FIG. 11D, so that a layer of insulation material 355 remains on the outside region of hole 328. This layer of insulation material on outside region of hole 328 is shown as 329 in FIG. 11D. Second hole 328 is of a smaller size than first hole or opening 327. In the next step, as shown in FIG. 11E, an electrically conducting layer 370, such as a metal layer, is formed over the insulation layer 355 thereby filling hole 328 and forming an electrical contact between layer 370 and layer 305 thus completing the electrical contact.

In an alternate procedure, a second processing sequence can be used where, after forming the structure as shown in FIG. 11C, an electrically conducting layer, such as a metal layer, is deposited over insulation layer 355 and then a laser or other means as described above, is used to “fire” the electrically conducting layer over the region where hole 327 is located and heat and liquefy the electrically conducting layer in that region so that it melts through the insulation layer 355 in hole 327 and forms an electrical contact with layer 305. This firing is accomplished so that a layer of insulation material 355 remains between the contact and layer 325. Such layer is shown in FIG. 11D as 329.

When referring herein to a layer positioned over another layer or over a wafer, and unless stated otherwise, it does not necessarily mean that such layer is positioned directly on and in contact with such other layer or wafer. Layers of other materials may be present between such layers or between such layer and the wafer.

Unless specified otherwise herein, silicon nitride preferably means hydrogenated silicon nitride which is formed by PECVD. Such silicon nitride formed by PECVD has a stoichiometry that is close to Si₃N₄. Methods for depositing layers of a- Si:H , with or without dopants such as phosphorus or boron, or other elements such as nitrogen or carbon, are well know in the art. However, general conditions for depositing such layers by PECVD, using a mixture of silane in hydrogen are substrate temperatures of about 100° C. to about 250° C., and pressures of about 0.05 to about 5 Torr. Methods for depositing layers of silicon nitride are also well known. However, general conditions for depositing such layers by PECVD using a mixture of silane and ammonia are substrate temperatures of about 200° C. to about 450° C., and pressures of about 0.05 to about 2 Torr.

The photovoltaic cells of this invention have high efficiency in converting light energy into electrical energy. Photovoltaic cells of this invention made using a monocrystalline silicon wafer, preferably of an area of about 100 to about 250 square centimeters, can have an efficiency of at least about 20%, and can have efficiency of up to or of at least about 23%. As used herein, the efficiency of the photovoltaic cells made by the process of this invention is measured using the standard test conditions of AM 1.5 G at 25° C. using 1000 W/m² (1000 watts per square meter) illumination where the efficiency is the electrical energy output of the cell over the light energy input, expressed as a percent.

The photovoltaic cells of this invention can be used to form modules where, for example, a plurality of such cells are electrically connected in a desired arrangement and mounted on or between a suitable supporting substrate such as a section of glass or other suitable material. Methods for making modules from photovoltaic cells are well known to those of skill in the art.

U.S. Provisional Patent Application Ser. No. 60/623,452, filed on Oct. 29, 2004, is incorporated herein by reference in its entirety.

Having described the invention, that which is claimed is:

1. A photovoltaic cell comprising:
a wafer comprising a semiconductor material of a first conductivity type, the wafer comprising a first light receiving surface and a second surface opposite the first surface;
a first passivation layer positioned over the first surface of the wafer;
a first electrical contact positioned over the second surface of the wafer;
a second electrical contact positioned over the second surface of the wafer and separated electrically from the first electrical contact;
a second passivation layer positioned over the second surface of the wafer in the region on the wafer that is at least between the first electrical contact and the second surface of the wafer; and
a layer comprising a semiconductor material of a conductivity opposite the conductivity of the wafer and positioned in the region between the second passivation layer and the first contact.

2. The photovoltaic cell of claim 1 wherein the semiconductor wafer comprises doped crystalline or multi-crystalline silicon.

3. The photovoltaic cell of claim 2 wherein the first passivation layer comprises silicon nitride, hydrogenated amorphous silicon, hydrogenated microcrystalline silicon or a combination thereof.

4. The photovoltaic cell of claim 3 wherein the first passivation layer comprises hydrogenated amorphous silicon and further comprises one or more of carbon or nitrogen or oxygen.

5. The photovoltaic cell of claim 4 wherein the passivation layer comprises nitrogen and the concentration of nitrogen is graded therein.

6. The photovoltaic cell of claim 3 wherein the passivation layer comprises silicon nitride.

7. The photovoltaic cell of claim 6 wherein the silicon nitride is formed by PECVD.

8. The photovoltaic cell of claim 2 wherein the second passivation layer comprises hydrogenated amorphous silicon, hydrogenated microcrystalline silicon or a combination thereof.

9. The photovoltaic cell of claim 1 wherein the semiconductor material of conductivity opposite the conductivity of the wafer comprises hydrogenated amorphous silicon, hydrogenated microcrystalline silicon, or a combination thereof.

10. The photovoltaic cell of claim 1 wherein the wafer further comprises a diffusion length and wherein the diffusion length is greater than the thickness of the wafer.

11. The photovoltaic cell of claim 1 wherein the first and second electrical contacts are positioned on the wafer in an interdigitated pattern.

12. The photovoltaic cell of claim 11 wherein the wafer has a diffusion length and distance between the center of the second contact to an edge of the first contact that is closest to the second contact is less than the diffusion length.

13. The photovoltaic cell of claim 1 comprising at least one anti-reflective layer on the first surface.

14. The photovoltaic cell of claim 1 wherein the first surface is textured.

15. The photovoltaic cell of claim 1 wherein the second electrical contact comprises an electrically conducting metal positioned directly on or in the second surface of the wafer.

16. The photovoltaic cell of claim 15 further comprising a BSF positioned between the second contact and the wafer.

17. The photovoltaic cell of claim 1 wherein the second contact comprises point contacts.

18. The photovoltaic cell of claim 17 wherein an insulating layer is positioned between at least a portion of the point contacts and the first contact.

19. The photovoltaic cell of claim 18 wherein insulation layer comprises silicon nitride.

20. The photovoltaic cell of claim 17 wherein the point contacts are formed by laser firing.

21. The photovoltaic cell of claim 17 wherein the center-to-center spacing of adjacent point contacts is in the range of about 100 microns to about 1 mm.

22. The photovoltaic cell of claim 17 comprising a passivation layer between the point contacts and the wafer.

23. A method for making a photovoltaic cell comprising (a) depositing a first passivation layer on a first surface of a wafer comprising a semiconductor material; (b) depositing a second passivation layer on a second surface of the wafer; (c) depositing over the second passivation layer a layer of semiconductor material having conductivity type opposite the wafer; (d) optionally depositing a TCO layer over the layer of semiconductor material; (e) depositing a first electrical contact layer over the layer of semiconductor material or, if present, the TCO layer; (f) forming a plurality of holes through at least the first electrical contact layer and the TCO layer if present, (g) depositing a layer of insulating material over the first electrical contact layer and into the holes; (h) depositing a second electrical contact layer over the insulating layer; and (i) forming a plurality of point contacts from the second electrical contact layer to the wafer.

24. The method of claim 23 wherein the wafer comprises silicon and has a diffusion length, and the thickness of the wafer is less than the diffusion length.

25. The method of claim 23 wherein the holes are round.

26. The method of claim 24 wherein the holes are spaced center-to-center about 100 microns to about 1 mm.

27. The method of claim 23 wherein the point contacts are formed by laser firing the second contact layer through the insulating layer.

28. The method of claim 23 wherein the insulating layer is silicon nitride.

29. A method for forming an electrical contact between an electrical conducting layer and a second layer, where there is at least a third layer positioned between the electrical conducting layer the second layer, method comprising:
forming a first opening in the third layer;
forming an insulating layer comprising an insulating material over the third layer wherein the insulating material fills the first opening,
forming a second opening in the insulation layer inside an area of the first opening leaving a region of the insulation material along a perimeter of the second opening and where the second opening,
forming a layer of electrical conducting material over the insulation layer and filling the second opening thereby forming an electrical contact between the electrical conduction layer and the second layer.

30. The method of claim 29 wherein the second opening extends to the second layer.

31. A method for forming an electrical contact between an electrical conducting layer and a second layer, where there is at least a third layer positioned between the electrical conducting layer the second layer, method comprising:
forming a first opening in the third layer;
forming an insulating layer comprising an insulating material over the third layer wherein the insulating material fills the first opening,
forming a layer of electrical conducting material over the insulation layer, heating the electrical conducting layer in a region over the first opening so as to cause the electrical conducting layer to liquefy and melt through the insulation material in the first opening and form an electrical contact with the second layer.

32. An electrical contact made by the method of claim 29.

33. An electrical contact made by the method of claim 31.

34. A method for making a photovoltaic cell comprising (a) depositing a first passivation layer on a first surface of a wafer comprising a semiconductor material; (b) depositing a second passivation layer on a second surface of the wafer; (c) depositing over the second passivation layer a layer of semiconductor material having conductivity type opposite the wafer; (d) optionally depositing a TCO layer over the layer of semiconductor material having a conductivity opposite the wafer; (e) depositing a first electrical contact layer over the semiconductor material having a conductivity opposite the wafer or, if present, the TCO layer; (f) removing at least the layers formed in steps (d) and (e) in a desired pattern thereby a exposing an area on the wafer without layers formed in steps (d) and (e); (g) depositing third passivation layer over the exposed area formed in step (f); (h) optionally depositing a semiconductor layer having a conductivity type the same as the wafer over the third passivation layer; (i) optionally depositing a second TCO layer over the third passivation layer or, if present, over the semiconductor layer having a conductivity type the same as the wafer; (j) depositing a second electrical contact layer over the third passivation layer or, if present, over the semiconductor layer having a conductivity type the same as the wafer, or, if present, over the second TCO layer; (k) forming a gap between the first electrical contact layer and the second electrical contact layer to electrically separate the first electrical contact layer from the second electrical contact layer thereby forming electrically separated electrical contacts.

35. The method of claim 34 wherein the electrical contacts are in an interdigitated pattern.

36. The method of claim 34 wherein the layers in step (f) are removed by laser ablation and the gaps in step (k) are formed by laser ablation.

37. A method for making a photovoltaic cell comprising (a) depositing a first passivation layer on a first surface of a wafer comprising a semiconductor material; (b) forming a first electrical contact on the second surface of the wafer in a desired pattern; (c) depositing a second passivation layer on a second surface of the wafer; (c) depositing over the second passivation layer a layer of semiconductor material having conductivity type opposite the wafer; (d) optionally depositing a TCO layer over the layer of semiconductor material having a conductivity opposite the wafer; (e) depositing a second electrical contact layer over the semiconductor material or, if present, the TCO layer; (k) forming a gap between the first electrical contact layer and the second electrical contact layer to electrically separate the first electrical contact layer from the second electrical contact layer thereby forming electrically separated electrical contacts.

38. The method of claim 37 wherein the electrical contacts are in an interdigitated pattern.

39. The method of claim 37 wherein the gap in step (k) is formed by laser ablation.

40. The method of claim 25 wherein the holes have a diameter of about 5 microns to about 50 microns.

41. The photovoltaic cell of claim 22 comprising a doped semiconductor layer having a conductivity the same as the wafer and is positioned between the point contact and the wafer.

42. The method of claim 34 wherein in step (f) layers formed in steps (b) through (e) are removed.
